(19) United States
(12) Patent Application Publication
(10) Pub. No.: US 2015/0302909 A1
(43) Pub. Date: Oct. 22, 2015

(54) SEMICONDUCTOR MEMORY APPARATUS AND OPERATING METHOD OF THE SAME

(71) Applicant: SK hynix Inc., Icheon-si Gyeonggi-do (KR)

(72) Inventors: Chang Hyun KIM, Icheon-si Gyeonggi-do (KR); Choung Ki SONG, Icheon-si Gyeonggi-do (KR)

(21) Appl. No.: 14/457,976

(22) Filed: Aug. 12, 2014

(30) Foreign Application Priority Data
Apr. 22, 2014 (KR) 10-2014-0048324

(51) Int. Cl. G11C 8/18; G11C 8/10

(52) U.S. Cl. CPC G11C 8/18; G11C 8/10

(57) ABSTRACT

A semiconductor memory apparatus includes a delay control portion configured to generate a plurality of control signals by performing subtraction operation on a CL information and an AL information; and a delay portion configured to decide a delay amount, delay an input signal by the delay amount, and output the delayed input signal as a delay signal in response to the plurality of control signals.

### CROSS-REFERENCES TO RELATED APPLICATION

The present application claims priority under 35 U.S.C. §119(a) to Korean application number 10-2014-0048324 filed on Apr. 22, 2014, in the Korean Intellectual Property Office, which is incorporated herein by reference in its entirety.

### BACKGROUND

1. Technical Field

Embodiments of the present invention generally relate to a semiconductor integrated circuit, and more particularly, in one or more embodiments, to a semiconductor memory apparatus and an operating method of the same.

2. Related Art

A semiconductor memory device refers to the semiconductor devices used to store data, and output stored data therein. Over the years, the need for high-speed systems has driven the development of high-speed, high-bandwidth semiconductor memory apparatus.

For example, modern semiconductor memory devices are synchronized with the system clock so that a memory controller can tightly control the semiconductor memory devices.

Where the memory controller issues commands, semiconductor memory devices may hold the commands internally for a predetermined duration before executing, to improve the efficiency of its operations.

### SUMMARY

In an embodiment of the present invention, a semiconductor memory apparatus may include a delay control portion configured to generate a plurality of control signals by performing subtraction operation to a CL information and an AL information; and a delay portion configured to decide a delay amount, delay an input signal with the decided delay amount, and output the delayed input signal as a delay signal in response to the plurality of control signals.

In an embodiment of the present invention, a semiconductor memory apparatus may include a coarse delay part configured to have delay amounts corresponding to one or more predetermined periods of a clock; a fine delay part configured to have delay amounts smaller than the predetermined periods of the clock; and a delay control portion configured to decide a delay amount of each of the coarse delay part and the fine delay part by performing subtraction operation to a CL information and an AL information.

In an embodiment of the present invention, an operating method of a semiconductor memory apparatus may include receiving a CL information and an AL information; decoding the CL information and the AL information; performing subtraction operation to the decoded CL information and the decoded AL information; generating a control signal based on result of the subtraction operation; deciding a delay amount in response to the control signal; and delaying an input signal with the decided delay amount, and outputting the delayed input signal.

In an embodiment of the present invention, an electronic system may include a subtraction part configured to subtract a first code, which represents a first latency element, from a second code, which represents a second latency element, and a delay portion configured to adjust a delay amount for command signals to be executed in response to the result of the subtraction operation.

### BRIEF DESCRIPTION OF THE DRAWINGS

Features, aspects and embodiments are described in conjunction with the attached drawings, in which:

FIG. 1 is a block diagram illustrating a semiconductor memory apparatus in accordance with an embodiment of the present disclosure,

FIG. 2 is a circuit diagram illustrating a delay portion shown in FIG. 1,

FIG. 3A-3B relate to a latency table illustrating an operation method of a semiconductor memory apparatus in accordance with an embodiment of the present disclosure, and

FIG. 4 is a flow chart illustrating an operating method of a semiconductor memory apparatus in accordance with an embodiment of the present disclosure.

### DETAILED DESCRIPTION

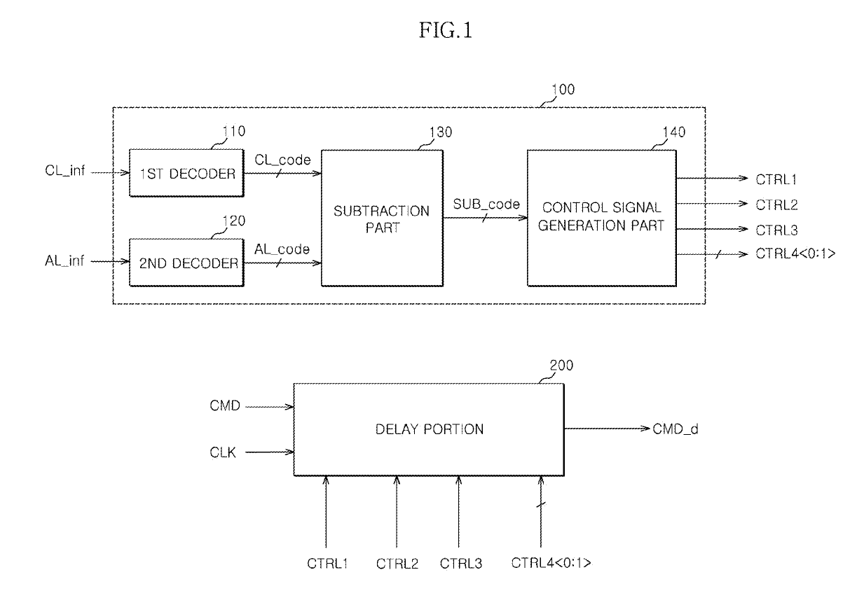

An example of a semiconductor memory apparatus in accordance with an embodiment of the present disclosure is shown in FIG. 1.

Referring to FIG. 1, a semiconductor memory apparatus in accordance with an embodiment of the present disclosure may include a delay control portion 100 and a delay portion 200.

The delay control portion 100 may generate first to fourth control signals CTRL1, CTRL2, CTRL3, and CTRL4<0:1> by performing subtraction operation in response to a Column Address Strobe (hereinafter referred to as “CAS”) Latency (CL) information CL_inf and an Additive Latency (AL) information AL_inf. For example, the delay control portion 100 may generate first to fourth control signals CTRL1, CTRL2, CTRL3, and CTRL4<0:1> by subtracting the AL information AL_inf from the CL information CL_inf.

The delay portion 200 may decide a delay amount, delay an input signal CMD by the delay amount, and output the delayed input signal CMD as a delay signal CMD_d in response to the first to fourth control signals CTRL1, CTRL2, CTRL3, and CTRL4<0:1>. For example, the input signal CMD may be an external command inputted from outside of the semiconductor memory apparatus. For example, the input signal CMD may be an internal command which has been initiated by loading external commands into the semiconductor memory apparatus. The delay portion 200 may decide the delay amount on the basis of a clock CLK in response to the first to fourth control signals CTRL1, CTRL2, CTRL3, and CTRL4<0:1>. For example, the delay signal CMD_d may outputted after a certain number of clock cycles determined in the delay portion 200.

The delay control portion 100 may include first and second decoders 110 and 120, a subtraction part 130, and a control signal generation part 140.

The first decoder 110 may generate a CL code CL_code by decoding the CL information CL_inf.

The second decoder 120 may generate an AL code AL_code by decoding the AL information AL_inf. The first and second decoders 110 and 120 may be configured so that the CL code CL_code and the AL code AL_code may have the same numbers of bits.

The subtraction part 130 may generate a subtraction code SUB_code by subtracting the AL code AL_code from the CL code CL_code. For example, the subtraction part 130 may generate the subtraction code SUB_code having a value of decimal 5 when the CL code CLcode has a value of decimal 7 and the AL code AL_code has a value of decimal 2.

The control signal generation part 140 may generate the first to fourth control signals CTRL1, CTRL2, CTRL3, and CTRL4<0:1> in response to the subtraction code SUB_code. For example, the control signal generation part 140 may generate the first to fourth control signals CTRL1, CTRL2, CTRL3, and CTRL4<0:1> so that the delay amount of the delay portion 200 may increase as the code value of the subtraction code SUB_code increases.

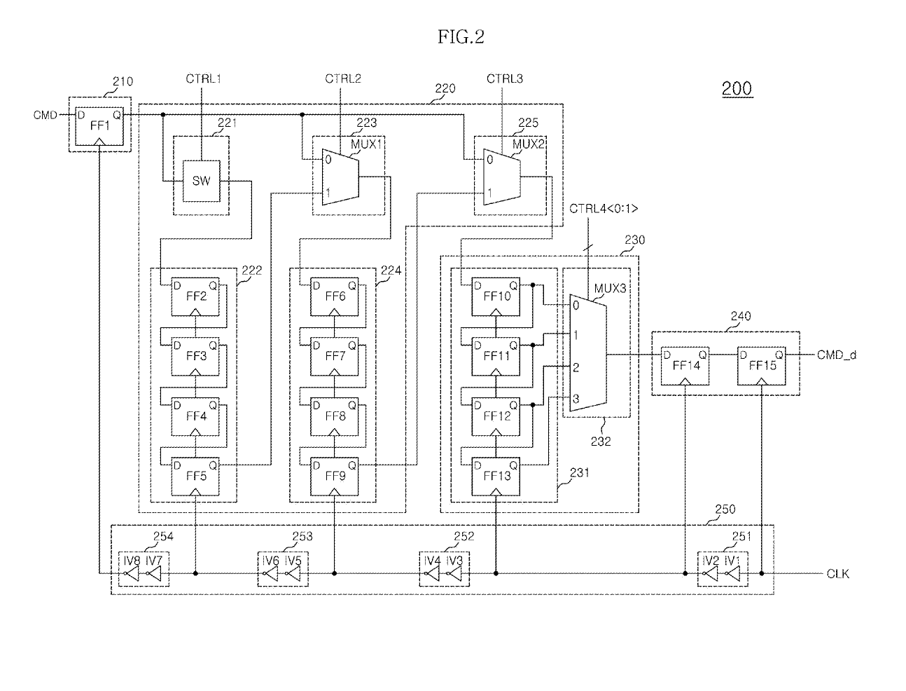

Referring to FIG. 2, the delay portion 200 may include a signal input part 210, a coarse delay part 220, a fine delay part 230, a default delay part 240, and a delayed clock generation part 250.

The signal input part 210 may receive the input signal CMD in response to the clock CLK. For example, the signal input part 210 may receive the clock CLK, which may be delayed by the delayed clock generation part 250. For example, the clock CLK, which the signal input part 210 receives, may be delayed by the maximum delay amount of the delayed clock generation part 250.

The signal input part 210 may include a first flip-flop FF1. The first flip-flop FF1 may receive the input signal CMD at its input node, and receive the clock CLK, which may be delayed by the delayed clock generation part 250, at its clock input node. For example, the clock CLK, which the signal input part 210 receives, may be delayed by the maximum delay amount of the delayed clock generation part 250.

The coarse delay part 220 may include a switching unit 221, a first predetermined period delay unit 222, a first signal selection unit 223, a second predetermined period delay unit 224, and a second signal selection unit 225.

The switching unit 221 may decide whether or not to input an output signal of the signal input part 210 to the first predetermined period delay unit 222 in response to the first control signal CTRL1. For example, the switching unit 221 may input the output signal of the signal input part 210 to the first predetermined period delay unit 222 when the first control signal CTRL1 is enabled. The switching unit 221 may prevent the output signal of the signal input part 210 from being input to the first predetermined period delay unit 222 when the first control signal CTRL1 is disabled. The switching unit 221 may comprise a switch W.

The first predetermined period delay unit 222 may delay an output signal of the switching unit 221 by a predetermined delay amount, which may correspond to one or more periods of the clock CLK. For example, the first predetermined period delay unit 222 may delay the output signal of the switching unit 221 by a delay amount corresponding to four periods of the clock CLK.

The first predetermined period delay unit 222 may include second to fifth flip-flops FF2 to FF5, which are serially coupled. For example, the second flip-flop FF2 may receive the output signal of the switching unit 221, the third flip-flop FF3 may receive an output signal of the second flip-flop FF2, the fourth flip-flop FF4 may receive an output signal of the third flip-flop FF3, and the fifth flip-flop FF5 may receive an output signal of the fourth flip-flop FF4. Each of the second to fifth flip-flops FF2 to FF5 may receive the clock CLK, which is delayed by a delay amount smaller than the delay amount of the clock CLK inputted to the signal input part 210.

The first signal selection unit 223 may select and output one of an input signal of a first input node 0 and an input signal of a second input node 1 in response to the second control signal CTRL2. For example, the first signal selection unit 223 may select and output the input signal of the first input node 0 when the second control signal CTRL2 is enabled. The first signal selection unit 223 may select and output the input signal of the second input node 1 when the second control signal CTRL2 is disabled. The first signal selection unit 223 may receive the output signal of the signal input part 210 at the first input node 0, and receive an output signal of the first predetermined period delay unit 222 at the second input node 1. The first signal selection unit 223 may include a first multiplexer MUX1.

The second signal selection unit 224 may delay an output signal of the first signal selection unit 223 with a delay amount corresponding to predetermined period(s) of the clock CLK. For example, the second predetermined period delay unit 224 may delay the output signal of the first signal selection unit 223 with the delay amount corresponding to four periods of the clock CLK.

The second predetermined period delay unit 224 may include sixth to ninth flip-flops FF6 to FF9, which are serially coupled. For example, the sixth flip-flop FF6 may receive the output signal of the first signal selection unit 223, the seventh flip-flop FF7 may receive an output signal of the sixth flip-flop FF6, the eighth flip-flop FF8 may receive an output signal of the seventh flip-flop FF7, and the ninth flip-flop FF9 may receive an output signal of the eighth flip-flop FF8. The second predetermined period delay unit 224 may receive the clock CLK, which is delayed by a delay amount smaller than the delay amount of the clock CLK inputted to the first predetermined period delay unit 222.

The second signal selection unit 225 may select and output one of an input signal of a first input node 0 and an input signal of a second input node 1 in response to the third control signal CTRL3. For example, the second signal selection unit 225 may select and output the input signal of the first input node 0 when the third control signal CTRL3 is enabled. The second signal selection unit 225 may select and output the input signal of the second input node 1 when the third control signal CTRL3 is disabled. The second signal selection unit 225 may receive the output signal of the signal input, part 210 at the first input node 0, and receive an output signal of the second predetermined period delay unit 224 at the second input node 1. The second signal selection unit 225 may include a second multiplexer MUX2.

The fine delay part 230 may decide a delay amount, which is equal to or smaller than the delay amount of the first and second predetermined period delay units 222 and 224, delay the output signal of the second signal selection unit 225 by the delay amount, and output the delayed output signal of the second signal selection unit 225 in response to the fourth control signal CTRL4<0:1>, which may have four combinations. For example, the fine delay part 230 may delay the output signal of the second signal selection unit 225 by a delay amount corresponding to one period of the clock CLK, and output the delayed output signal of the second signal selection unit 225 in response to a first combination of the fourth control signal CTRL4<0:1>. The fine delay part 230 may delay the output signal of the second signal selection unit 225 by a delay amount corresponding to two periods of the clock CLK, and output the delayed output signal of the second signal selection unit 225 in response to a second combination of the fourth control signal CTRL4<0:1>. The fine delay part 230 may delay the output signal of the second signal selection unit 225 by a delay amount corresponding to three periods of the clock CLK, and output the delayed output signal of the second signal selection unit 225 in response to a third combination of the fourth control signal CTRL4<0:1>. The fine delay part 230 may delay the output signal of the second signal selection unit 225 by a delay amount corresponding to four periods of the clock CLK, and output the delayed output signal of the second signal selection unit 225 in response to a fourth combination of the fourth control signal CTRL4<0:1>.

The fine delay part 230 may include a delay-in-clocks unit 231 and a third signal selection unit 232.

The delay-in-clocks unit 231 may include tenth to thirteenth flip-flops FF10 to FF13, which are serially coupled. The tenth flip-flop FF10 may receive the output signal of the second signal selection unit 225, the eleventh flip-flop FF11 may receive an output signal of the tenth flip-flop FF10, the twelfth flip-flop FF12 may receive an output signal of the eleventh flip-flop FF11, and the thirteenth flip-flop FF13 may receive an output signal of the twelfth flip-flop FF12, each of the tenth to thirteenth flip-flops FF10 to FF13 may receive the clock CLK, which is delayed with a delay amount smaller than the delay amount of the dock CLK inputted to the second predetermined period delay unit 224.

The third signal selection unit 232 may select one of the output signals of the tenth to thirteenth flip-flops FF10 to FF13 and output selected one in response to the fourth control signal CTRL4<0:1>. For example, the third signal selection unit 232 may select one of a signal inputted to a first input node 0, a signal inputted to a second input node 1, a signal inputted to a third input node 2, and a signal inputted to a fourth input node 3 and output selected one in response to the fourth control signal CTRL4<0:1>, which may have four combinations. For example, the third signal selection unit 232 may receive the output signal of the tenth flip-flop FF10 at the first input node 0, receive the output signal of the eleventh flip-flop FF11 at the second input node 1, receive the output signal of the twelfth flip-flop FF12 at the third input node 2, and receive the output signal of the thirteenth flip-flop FF13 at the fourth input node 3. The third signal selection unit 232 may output the output signal of the tenth flip-flop FF10 received at the first input node 0 when all of the fourth control signal CTRL4<0:1> is enabled. The third signal selection unit 232 may output the output signal of the eleventh flip-flop FF11 received at the second input node 1 when a first signal CTRL4<0> of the fourth control signal CTRL4<0:1> is enabled and a second signal CTRL4<1> of the fourth control signal CTRL4<0:1> is disabled. The third signal selection unit 232 may output the output signal of the twelfth flip-flop FF12 received at the third input node 2 when the first signal CTRL4<0> of the fourth control signal CTRL4<0:1> is disabled and the second signal CTRL4<1> of the fourth control signal CTRL4<0:1> is enabled. The third signal selection unit 232 may output the output signal of the thirteenth flip-flop FF13 received at the fourth input node 3 when all of the fourth control signal CTRL4<0:1> is disabled. The third signal selection unit 232 may include a third multiplexer MUX3.

The default delay part 240 may delay an output signal of the third signal selection unit 232 by a delay amount corresponding to in the period of the clock CLK or a multiple of the period of the clock CLK, and output the delayed output signal of the third signal selection unit 232 as the delay signal CMD_d. For example, the default delay part 240 may delay the output signal of the third signal selection unit 232 by a delay amount corresponding to two periods of the clock CLK, and output the delayed output signal of the third signal selection unit 232 as the delay signal CMD_d. The default delay part 240 may include fourteenth and fifteenth flip-flops FF14 and FF15, which are serially coupled. The fourteenth flip-flop FF14 may receive the clock CLK, which is delayed by the same delay amount as the clock CLK 2o inputted to the delay-in-clocks unit 231. The fifteenth flip-flop FF15 may receive the clock CLK, which is delayed by a delay amount smaller than the delay amount of the clock CLK inputted to the fourteenth flip-flop FF14. For example, the fifteenth flip-flop FF15 may receive the clock CLK without delay.

The delayed clock generation part 250 may delay the clock CLK by various delay amounts, and provide the clock CLK, which has been delayed by various delay amounts, to the first and second predetermined period delay units 222 and 224, the delay-in-docks unit 231, and the default delay part 240. For example, the delayed clock generation part 250 may include first to fourth delay units 251, 252, 253, and 254, which are serially coupled. Each of the first to fourth delay units 251, 252, 253, and 254 may have even number of inverters so as not to provide inverted clock signal to the first and second predetermined period delay units 222 and 224, the delay-in-clocks unit 231, and the default delay part 240. The dock CLK may be provided to the fifteenth flip-flop FF15 of the default delay part 240. The first delay unit 251 may delay the clock CLK, and provide the delayed clock CLK to the fourteenth flip-flop FF14 of the default delay part 240 and the tenth to thirteenth flip-flops FF10 to FF13 of the delay-in-clocks unit 231. The second delay unit 252 may delay the delayed clock CLK, which has been delayed at the first delay unit 251, and provide the delayed clock CLK, which has been delayed at the second delay unit 252, to the sixth to ninth flip-flops FF6 to FF9 of the second predetermined period delay unit 224. The third delay unit 253 may delay the delayed clock CLK, which has been delayed at the second delay unit 252, and provide the delayed clock CLK, which has been delayed at the third delay unit 253, to the second to fifth flip-flops FF2 to FF5 of the first predetermined period delay unit 222. The fourth delay unit 254 may delay the delayed clock CLK, which has been delayed at the third delay unit 253, and provide the delayed clock CLK, which has been delayed at the fourth delay unit 254, to the first flip-flop FF1 of the signal input part 210.

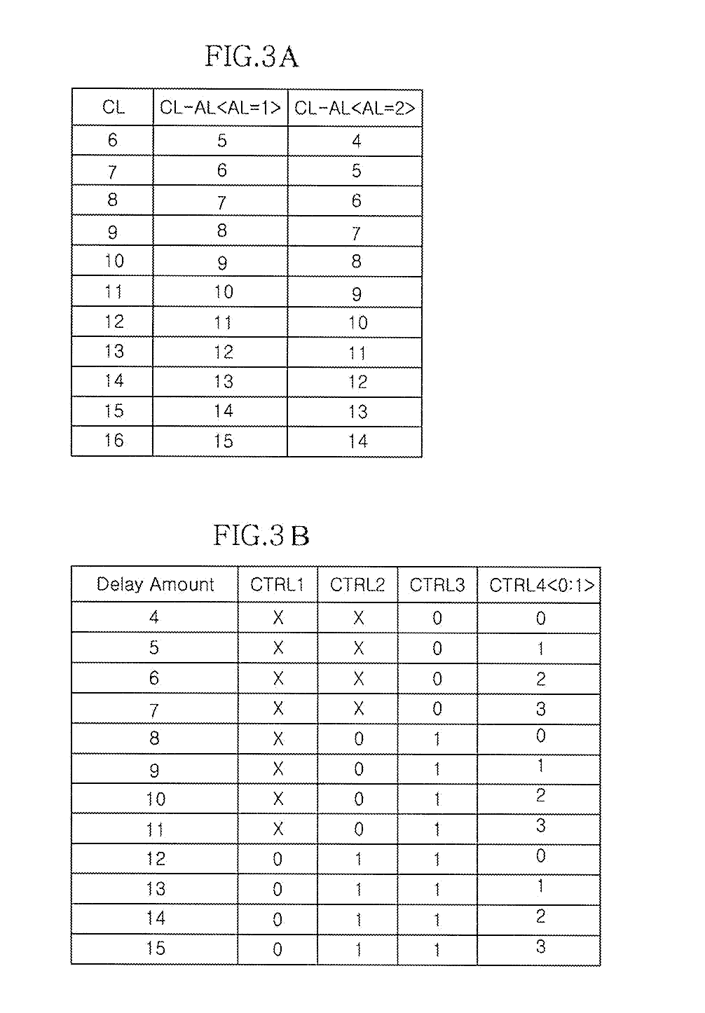

The operation of the semiconductor memory apparatus in accordance with an embodiment of the present disclosure described above will be described as follows in reference with FIG. 3A-3B.

A semiconductor memory apparatus, which has been received a command from an external controller, may hold the commands internally for a predetermined duration. The CAS latency (CL) is the delay time between the moment a memory controller requests a memory to access a particular memory column, and the moment the data in the particular memory column is read. The semiconductor memory apparatus may hold commands, received from the memory controller, internally for the duration of additive latency (AL).

The CL information CL_inf described with reference to FIG. 1 may include information with respect to the CAS latency (CL). The AL information AL_inf described with reference to FIG. 1 may include information with respect to the additive latency (AL). Such information may be set by a user or the external controller.

FIG. 3A illustrates that an input signal CMD shown in FIG. 1 may be delayed by the delay amount corresponding to predetermined periods of the clock CLK, and outputted as a delay signal CMD_d. For example, the input signal CMD may be delayed by the delay amount corresponding to five periods of the clock CLK, and outputted as the delay signal CMD_d when the CAS latency (CL) is six and the Additive latency (AL) is one. Also, the input signal CMD may be delayed by the delay amount corresponding to four periods of the dock, and outputted as the delay signal CMD_d when the CAS latency (CL) is six and the Additive latency (AL) is two. The input signal may be an external command Inputted from outside of the semiconductor memory apparatus. As illustrated in FIG. 3B, for example, the input signal CMD may be delayed by the delay amount corresponding to four to fifteen periods of the clock CLK, and outputted as the delay signal CMD_d. For the operation as illustrated in FIG. 3A, the semiconductor memory apparatus in accordance with an embodiment of the present disclosure may generate the subtraction code SUB_code by subtracting the value of the AL information AL_inf from the value of the CL information CL_inf, and generate the first to fourth control signals CTRL1, CTRL2, CTRL3, and CTRL4<0:1> according to the subtraction code SUB_code. Referring to FIG. 3B, the semiconductor memory apparatus in accordance with an embodiment of the present disclosure may decide the total amount of delay Delay Amount, by which the input signal CMD is delayed, delay the input signal CMD by the total amount of delay Delay Amount, and output a delayed input signal CMD as the delay signal CMD_d according to the first to fourth control signals CTRL1, CTRL2, CTRL3, and CTRL4<0:1>.

In other words, the subtraction code SUB_code, which is the result of subtraction operation of the AL information AL_inf and the CL information CL_inf, may correspond to the total amount of delay Delay Amount.

When the value of the total amount of delay Delay Amount is any value between four and seven, the second multiplexer MUX2 described with reference to FIG. 2 may transfer the signal received at the first input node 0 of the second multiplexer MUX2 to the fine delay part 230 in response to the third control signal CTRL3. Also, the third multiplexer MUX3 may output one of the signals received at the first to fourth input nodes 0 to 3 of the third multiplexer MUX3 to the default delay part 240 in response to the fourth control signal CTRL4<0:1>. For example, when the value of the total amount of delay Delay Amount is four, the input signal CMD may be delayed by the delay amount corresponding to four periods of the clocks CLK. The input signal CMD may be delayed by the first flip-flop FF1, the tenth flip-flop FF10, the fourteenth flip-flop FF14, and the fifteenth flip-flop FF15, and may be outputted as the delay signal CMD_d. When the value of the total amount of delay Delay Amount is five, the input signal CMD may be delayed by the delay amount corresponding to five periods of the clocks CLK. The input signal CMD may be delayed by the first flip-flop FF1, the tenth flip-flop FF10, the eleventh flip-flop FF11, the fourteenth flip-flop FF14, and the fifteenth flip-flop FF15, and may be outputted as the delay signal CMD_d. When the value of the total amount of delay Total_Latency is six, the input signal CMD may be delayed by the delay amount corresponding to six periods of the clocks CLK. The input signal CMD may be delayed by the first flip-flop FF1, the tenth to twelfth flip-flops FF10 to FF12, the fourteenth flip-flop FF14, and the fifteenth flip-flop FF15, and may be outputted as the delay signal CMD_d. When the value of the total amount of delay Total_Latency is seven, the input signal CMD may be delayed by the delay amount corresponding to seven periods of the clocks CLK. The input signal CMD may be delayed by the first flip-flop FF1, the tenth to fifteenth flip-flops F10 to FF15, and may be outputted as the delay signal CMD_d.

As described above, when the value of the total amount of delay Delay Amount is any value between four and seven, the output signal of the signal input part 210 may be inputted to the fine delay part 230 through the second multiplexer MUX2 in response to the third control signal CTRL3, and the third multiplexer MUX3 of the fine delay part 230 may select one of the signals received at the first to fourth input nodes 0 to 3 to the default delay part 240 in response to the fourth control signal CTRL4<0:1>.

When the value of the total amount of delay Delay Amount is any value between eight and eleven, the first multiplexer MUX1 may output the signal received at the first input node 0 of the first multiplexer MUX1 in response to the second control signal CTRL2, and the second multiplexer MUX2 may output the signal received at the second input node 1 of the second multiplexer MUX2 in response to the third control signal CTRL3. Therefore, the value of the total amount of delay Delay Amount may be any value between eight and eleven because the delay amount of four periods of the clock CLK, which corresponds to the delay amount of the sixth to ninth flip-flops FF6 to FF9, may be added to the case previously described.

Further, when the value of the total amount of delay Total_Latency is any value between twelve and fifteen, the switching unit 221 may be turned on in response to the first control signal CTRL1, the first multiplexer MUX1 may output the signal received at the second input node 1 of the first multiplexer MUX1 in response to the second control signal CTRL2, and the second multiplexer MUX2 may output the signal received at the second input node 1 of the second multiplexer MUX2 in response to the third control signal in CTRL3. Therefore, the value of the total amount of delay Delay Amount may be any value between twelve and fifteen because the delay amount of four periods of the clock CLK, which corresponds to the delay amount of second to fifth flip-flops FF2 to FF5, may be added to the case previously described.

As described above, the semiconductor memory apparatus in accordance with an embodiment of the present disclosure may include the subtraction part 130 subtracting the AL information AL_inf from the CL information CL_inf, and may delay the input signal CMD (e.g., external commands) through a plurality of flip-flops, the number of which corresponds to the total amount of delay (e.g., number of clock cycle may represent the total amount of delay), using the subtraction information (e.g., the subtraction code SUB_code). The delay signal CMD_d delayed by the plurality of flip-flops (e.g., delayed external command) may be used inside the semiconductor memory apparatus. The semiconductor memory apparatus in accordance with an embodiment of the present disclosure may delay input signals such as command signals by a delay amount required by an external controller through simple subtraction operation to improve the efficiency of the operations being performed in the semiconductor memory apparatus.

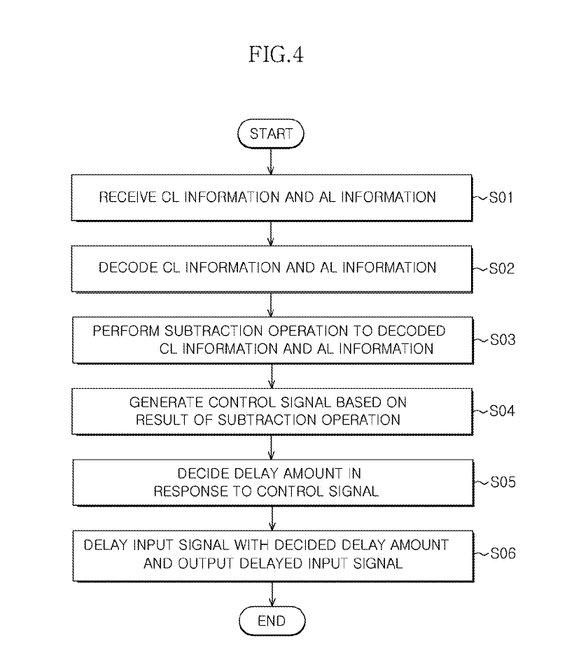

The operation method of the semiconductor memory apparatus in accordance with an embodiment of the present disclosure will be described with reference to FIG. 4.

Referring to FIG. 4, the operation method may include step S01 of receiving the CL information CL_inf and the AL information AL_inf, step 502 of decoding the received CL information CL_inf and AL information AL_inf, step 503 of performing subtraction operation on the decoded CL information CL_inf and AL information AL_Inf, step S04 of generating the first to fourth control signals CTRL1, CTRL2, CTRL3, and CTRL4<0:1> based on the result of the subtraction operation (e.g., the subtraction code SUBcode), step 505 of deciding the delay amount (e.g., total amount of delay Delay Amount) in response to the first to fourth control signals CTRL1, CTRL2, CTRL3, and CTRL4<0:1>, and step 506 of delaying the input signal CMD (e.g., command signal) by the delay amount and outputting the delay signal CMD_d (e.g., delayed input signal, delayed command signal). Step 905 of deciding the delay amount in response to the first to fourth control signals CTRL1, CTRL2, CTRL3, and CTRL4<0:1> may include a step of deciding a number of flip-flops, through which the input signal or the command passes in response to the first to fourth control signals CTRL1, CTRL2, CTRL3, and CTRL4<0:1>.

In an electronic system having memory components where latency time is defined with respect to the execution of operations of the memory components, a total latency may consist of two or more latency elements. For example, the total latency of a certain operation of DRAM may consist of CAS latency and additive latency. An electronic system in accordance with an embodiment of the present invention may include a subtraction part that may subtract a first code, which represents a first latency element, from a second code, which represents a second latency element, and a delay portion that may adjust a delay amount for command signals to be executed in response to the result of the subtraction operation.

While certain embodiments have been described above, it will be understood to those skilled in the art that the embodiments described are by way of example only. Accordingly, the stacked semiconductor apparatus and the semiconductor system capable of inputting signals through various paths should not be limited based on the described embodiments. Rather, the stacked semiconductor apparatus and the semiconductor system capable of inputting signals through various paths described herein should only be limited in light of the claims that follow when taken in conjunction with the above description and accompanying drawings.

What is claimed is:

1. A semiconductor memory apparatus comprising:
a delay control portion configured to generate a plurality of control signals by performing subtraction operation on a CL information and an AL information; and
a delay portion configured to decide a delay amount, delay an input signal by the delay amount, and output the delayed input signal as a delay signal in response to the plurality of control signals.

2. The semiconductor memory apparatus of claim 1, wherein the delay control portion subtracts the AL information from the CL information.

3. The semiconductor memory apparatus of claim 2, wherein the delay control portion comprises:
a first decoder configured to generate a CL code by decoding the CL information;
a second decoder configured to generate a AL code by decoding the AL information;
a subtraction part configured to generate a subtraction code by subtracting the AL code from the CL code; and
a control signal generation part configured to generate the plurality of control signals in response to the subtraction code.

4. The semiconductor memory apparatus of claim 3, the CL code and the AL code have the same numbers of bits.

5. The semiconductor memory apparatus of claim 3, wherein the control signal generation part generates the plurality of control signals so that the delay amount increases as a code value of the subtraction code increases.

6. The semiconductor memory apparatus of claim 1, wherein the delay portion comprises:
a signal input part configured to receive the input signal;
a coarse delay part configured to delay an output signal of the signal input part in response to a first part of the plurality of control signals;
a fine delay part configured to delay an output signal of the coarse delay part in response to a second part of the plurality of control signals; and
a default delay part configured to delay and output an output signal of the fine delay part.

7. The semiconductor memory apparatus of claim 6,
wherein the first part of the plurality of control signals includes first, second, and third control signals, and the second part of the plurality of control signals includes a fourth control signal, and
wherein the coarse delay part comprises:
a first predetermined period delay unit configured to have a delay amount corresponding to one or more predetermined periods of a clock;
a switching unit configured to input the output signal of the signal input part to the first predetermined period delay unit in response to the first control signal;
a second predetermined period delay unit configured to have a delay amount corresponding to one or more predetermined periods of the clock;
to a first signal selection unit configured to output one of the output signal of the signal input part and an output signal of the first predetermined period delay unit to the second predetermined period delay unit in response to the second control signal; and
a second signal selection unit configured to output one of the output signal of the signal input part and an output signal of the second predetermined period delay unit to the fine delay part in response to the third control signal.

8. The semiconductor memory apparatus of claim 7, each of the first and second predetermined period delay units, and the default delay part include a plurality of flip-flops, which are serially coupled.

9. The semiconductor memory apparatus of claim 6, wherein the fine delay part comprises:
a plurality of flip-flops, which are serially coupled; and
a signal selection unit configured to output one of output signals of the plurality of flip-flops in response to the fourth control signal.

10. A semiconductor memory apparatus comprising:
a coarse delay part configured to have delay amounts corresponding to one or more predetermined periods of a clock;
a fine delay part configured to have delay amounts smaller than the predetermined periods of the clock; and
a delay control portion configured to decide a delay amount of each of the coarse delay part and the fine delay part by performing subtraction operation on a CL information and an AL information.

11. The semiconductor memory apparatus of claim 10,
wherein the delay control portion generates a plurality of control signals by subtracting the AL information from the CL information.

12. The semiconductor memory apparatus of claim 10,
wherein the coarse delay part is configured to change the delay amounts by the unit of the predetermined periods of the clock in response to a first part of the plurality of control signals,
wherein the fine delay part is configured to change the delay amounts by the unit of one period of the clock in response to a second part of the plurality of control signals, and
wherein the predetermined periods of the clock are greater than the one period of the clock.

13. The semiconductor memory apparatus of claim 12,
wherein the first part of the plurality of control signals includes a first control signal, a second control signal, and a third control signal, and
wherein the coarse delay part comprises:
a first predetermined period delay unit configured to include a plurality of flip-flops, which are serially coupled;
a second predetermined period delay unit configured to include a plurality of flip-flops, which are serially coupled;
a switching unit configured to output an input signal to the first predetermined period delay unit in response to the first control signal;
a first signal selection unit configured to output one of the input signal and an output signal of the first predetermined period delay unit to the second predetermined period delay unit in response to the second control signal; and
a second signal selection unit configured to output one of the input signal and an output signal of the second predetermined period delay unit to the fine delay part in response to the third control signal.

14. The semiconductor memory apparatus of claim 13,
wherein the second part of the plurality of control signals includes a fourth control signal, and
wherein the fine delay part comprises:
a plurality of flip-flops, which are serially coupled; and
a third signal selection unit configured to select and output one of output signals of the plurality of flip-flops of the fine delay part in response to the fourth control signal.

15. An operating method of a semiconductor memory apparatus comprising:
receiving a CL information and an AL information;
decoding the CL information and the AL information;
performing subtraction operation to the decoded CL information and the decoded AL information;
generating a control signal based on result of the subtraction operation;
deciding a delay amount in response to the control signal; and
delaying an input signal by the delay amount, and outputting the delayed input signal.

16. The operating method of claim 15, wherein the deciding of the delay amount in response to the control signal decides a number of flip-flops, through which the input signal passes in response to the control signal.
